(19) United States
(12) Patent Application Publication
(10) Pub. No.: US 2017/0186662 A1
(43) Pub. Date: Jun. 29, 2017

(54) APPLYING PHASE SEPARATION OF A SOLVENT MIXTURE WITH A LOWER CRITICAL SOLUTION TEMPERATURE FOR ENHANCEMENT OF COOLING RATES BY FORCED AND FREE CONVECTION

(71) Applicant: RAMOT AT TEL AVIV UNIVERSITY, TEL AVIV (IL)

(72) Inventors: AMOS ULLMANN, Tel Mond (IL); Neima BRAUNER, Tel Aviv (IL); Pietro POESIO, Brescia (IT); Gian Paolo BERETTA, Brescia (IT); Stefano FARISE, Brescia (IT)

(21) Appl. No.: 15/309,589

(22) PCT Filed: May 13, 2015
(86) PCT No.: PCT/IL2015/050503

§ 371 Date: Nov. 8, 2016

Related U.S. Application Data
(60) Provisional application No. 61/992,257, filed on May 13, 2014.

(51) Int. Cl. H01L 23/36; H01L 23/473; F25B 15/02

(52) U.S. Cl. CPC H01L 23/36; F25B 15/02; H01L 23/473; F28F 13/00

(57) ABSTRACT

A method and system for cooling a device (preferably a micro-device), comprising cooling the device by using a lower critical solution temperature (LCST) mixture. Enhancement of heat transfer rates is achieved during phase separation of a two-component system (two-component mixture) with a LCST. Convective heat transfer rates in small diameter pipes and over a vertical (hot) plate are demonstrated.

### RELATED APPLICATIONS

This application claims priority from U.S. provisional patent Ser. No. 61/992,257 filing date May 13 2014, which is incorporated herein in its entirety.

### BACKGROUND OF THE INVENTION

The following references provide an illustration of the prior art:
[1] Collier, J. G., Thome, J. R., “Convective Boiling and Condensation,” 3rd ed., Oxford, University Press, Oxford (1994).
[2] Kandlikar, S. G., “History, Advances and Challenges in Liquid Flow and Flow Boiling Heat Transfer in Micro Channels—A Critical Review,” Journal of Heat Transfer, 134, 034001-1-034001-15 (2012).
[3] Kandlikar, S. G., “Heat Transfer Mechanisms during Flow Boiling in Micro Channels,” Journal of Heat Transfer, 126, 8-16 (2004).
[4] Gat, S., Brauner, N., Ullmann, A., “Heat Transfer Enhancement via Liquid-Liquid Phase Separation,” Proc. of the 13th Int. Heat Transfer Conf., Sydney Australia 13-18 August, paper No. HTE10 (2006).
[5] Gat, S., Brauner, N., Ullmann, A., “Heat Transfer Enhancement via Liquid-Liquid Phase Separation,” Int. J. Heat and Mass Transfer, 52, 1385-1399 (2009).
[6] Poesio, P., Lezzi, A. M., Beretta, G. P., “Convective heat transfer enhancement induced by spinodal decomposition,” Physical Review E, 75(6) No. 066306 (2007).
[7] Di Fede, F., Poesio, P., Beretta, G. P., “Heat transfer enhancement in a small pipe by spinodal decomposition of a low viscosity, liquid-liquid, strongly non-regular mixture,” Int. J. Heat Mass Transfer, 55 897-906 (2012).
[8] Farise, S., Franzoni, A., Poesio, P., Beretta, G. P., “Heat transfer enhancement by spinodal decomposition in micro heat exchangers,” Experimental Thermal and Fluid Science, 42 38-45 (2012).
[9] Ullmann, A., Maevski, K., Brauner, N., “Enhancement of Forced and Free Convection Heat Transfer Rates by Inducing Liquid-Liquid Phase Separation of a Partially-Miscible Equal-Density Binary System, ” Int. J. of Heat and Mass Transfer, 70, 363-377 (2014).
[10] Francis, A. W., “Critical Solution Temperatures,” American Chemical Society, Washington (1943).
[11] Sorensen, J. M., Arlt, W., “Liquid-Liquid Equilibrium Data Collection: Ternary Systems,” Chemistry Data Series, Dechema, 5(2) 333-339 (1980).
[12] Mauri, R., Shinnar, R., Triantafyllou, G., “Spinodal decomposition in binary mixtures,” Phys. Rev. E, 53(3) 2613-2623 (1995).
[13] Ullmann, A., Gat, S., Ludmer, Z., Brauner, N., “Phase Separation of Partially Miscible Solvent Systems: Flow Phenomena and Heat and Mass transfer Applications”, Rev. Chem. Eng., 24(4-5) 159-262 (2008).
[14] Rogers, D. W., Scher, J., “Cloud point analysis of microliter samples determination of water in six common solvents,” Talanta, 16 1579-1582 (1969).
[15] Kohler, F., Rice, O. K., “Coexistence Curve of The Triethylamine-Water System,” J. Chem. Phys., 26 1614-1618 (1957).
[16] Rothmund, V., “Die Gegenseitige Loslichket von Flussigkeiten and der kritische Losungspunkt,” Z. Phys. Chem. (Leipzig), 26, 433-492 (1898).
[17] Yaws' Handbook of Thermodynamic and Physical Properties of Chemical Compounds, Carl L Yaws, Knovel (2003).
[18] Bertrand, G. L., Larson, J. W., Helper, L. G., “Thermochemical Investigations of the Water-Triethylamine System,”, J. Chem. Phys., 72, 4194-4197 (1968).
[19] Flewelling, A. C., DeFonseka, R. J., Khaleeli, N., Partee, J., Jacobs, D. T., “Heat Capacity Anomaly Near The Lower Critical Consolute Point of Triethylamine-Water, ” J. Chem. Phys., 104, 8048-8057 (1996).
[20] Thoen, J., Bloemen, E., Van Dad, W., “Heat Capacity of the Binary Liquid System Triethylamine-Water Near The Critical Solution Point,” J. Chem. Phys., 68, 735-744 (1978).
[21] Hausen, H., “Darstellung des warmeuberganges in rohren durch verallgemeinerte potenzbeziehungen,” VDI Z., 4, 91 (1943).
[22] Churchill, S. W., Chu,. H. H. S., “Correlating Equations for Laminar and Turbulent Free Convection from a Horizontal Cylinder,” Int. J. Heat Mass Transfer, 18, 1049-1053 (1975).

Heat transfer enhancement due to phase change is well-known in vapor-liquid phase transition (i.e. boiling, condensation). The large density difference between the two phases is the main driving force for vapor bubble detachment from the heated surface, which enhances heat transfer [1]. The application of convective boiling for heat removal is constrained by the critical heat flux (CHF). At the CHF the surface is covered by vapor (dry-out), leading to a very large increase in the surface temperature. This problem is crucial in micro channels, when the size of the bubble reaches the channel diameter already before its detachment and earlier dry-out occurs. Additionally, the fast growth of elongated bubbles results in instabilities when operating in parallel channels. To overcome the above limitations convective cooling by single phase flow is preferred in mini and micro channels [1-3].

The possibility of using phase transition of liquid-liquid systems to enhance the single phase heat transfer rates was examined [4-9]. The liquid-liquid systems used are partially miscible solvent systems with a Critical Solution Temperature (CST). Such systems can alter from a state of a single liquid phase, to a state of two separated liquid phases, by a small change of temperature. In liquid-liquid phase separation, density differences are much lower However, during the intermediate, non-equilibrium stages of phase separation, the chemical potential gradients are responsible for the so-called Korteweg capillary forces that result in self-propulsion of droplets. Inducing liquid-liquid phase separation at a cooled (hot) surface would in this case result in drop detachment, and consequently in inflow of fresh, cold liquid into the thermal boundary layer. Similarly to boiling, this pumping mechanism increases the rate of heat removal from the surface.

Temperature induced phase separation is encountered in solvent systems that possess either an Upper Critical Solution Temperature (UCST) or a Critical Solution Temperature (CST). In UCST systems the transition from a single-phase to two phases is brought about by reducing the temperature. While in Lower Critical Solution Temperature (LCST) systems, phase separation occurs with increasing the temperature. The boundary between the complete miscibility of the system and the region where the system separates into two-phases is given by the coexistence (binodal) curve. This curve provides the equilibrium compositions of the two separated phases as a function of temperature. Lists of binary and multi-component systems possessing a critical temperature and the equilibrium data can be found in Francis [10] and Sorensen and Arlt [11]. It is worth noting that the use of multi-component (e.g., 3 component) systems enable adjustment of the phase transition temperature to the desired operation range [5].

Imposing a temperature change (and/or change of composition) on the system that brings it into the coexistence curve, will result in phase separation. There are two types of phase separation: spinodal decomposition, when the system is brought to the unstable region within the spinodal curve (e.g., systems with a critical composition) and nucleation for systems that pass through a meta-stable region (e.g. off-critical composition systems). Unlike nucleation, where activation energy is required to initiate the separation, spinodal decomposition involves the growth of any fluctuations whose wavelength exceeds a critical value [12]. More details and discussions on dynamics of phase separation and the characteristic morphology of the separating phases associated with critical and off-critical compositions is described in the literature (e.g., [13]). As mentioned above, the movement of the separating domains is initially driven by the Korteweg forces. Yet, when the domains become large enough (the size of the capillary length), buoyancy may dominate surface tension and the mixture further separates by gravity.

The potential of using liquid-liquid phase separation for enhancing the single phase heat transfer rates has been previously demonstrated. Poesio et al. [6] found an up to 10-fold reduction in the cooling time of separating (cooled) solvent systems in a closed cell as compared to cooling by conduction. Gat et al. [4-5] reported an increase by a factor of 2 of the average Nu number during phase separation of a three-component (water-ethanol-ethyl acetate) system flowing in a mini tube (2 mm i.d.). The free convection from the outer surface of the tube (4 mm o.d.) was also studied [5] and found to be enhanced (approximately by a factor of 2). In a recent study [9] it was found that phase separation can enhance significantly the forced and free convection heat transfer in small diameter pipes (by a factor of 2.5) even in a system with almost equal density of the separating phases, hence also in practically zero gravity systems. Unexpectedly, phase separation of the equal density solvent system over a vertical (cold) plate resulted in enhanced heat transfer rates (up to a factor of 2) compared to single phase free convention for the same temperature difference. Those experimental results are encouraging and show the potential for significant improvements in the cooling efficiency. However, all those experiments were conducted with UCST solvent systems, where the solvents served as the heat source. For cooling purposes heat sink is required, whereby a LCST system should be used. In addition, the selected system should meet technological requirements, such as the correct temperature range. Boiling can be avoided by increasing the pressure, and generally, the effect of the pressure on the equilibrium compositions versus temperature (i.e., coexistence curve) is mild. Price and environmental aspects should be considered as well.

### SUMMARY

According to an embodiment of the invention there may be provided a method for cooling a device, the method may include cooling the device by using a lower critical solution temperature (LCST) mixture.

The method may include cooling the device by providing the LCST mixture to at least one conduit of a cooling system, the at least one conduit is thermally coupled to the device when cooling the device. The thermal coupling may be obtained by contact or without contact.

One or more conduits of the at least one conduit may be connected to the device when cooling the device.

One or more conduits of the at least one conduit is not connected to the device when cooling the device.

A diameter of one or more conduits of the at least one conduit does not exceed few millimeters.

A diameter of one or more conduits of the at least one conduit does not exceed few microns.

A diameter of one or more conduits of the at least one conduit may be of an equal magnitude of a size of bubbles formed in the LCST mixture when the LCST mixture boils.

The method may include preventing the LCST mixture from boiling within one or more conduits of the at least one conduit.

A critical point of the LCST mixture may be within a temperature range to which an interior of one or more conduits of the at least one conduit is subjected by the device.

The LCST mixture may be arranged to undergo a liquid-liquid phase separation when a temperature of the device exceeds a predefined temperature.

The LSCT mixture may consist or essentially consist of water and triethyamine.

The LSCT mixture may include water, triethyamine and at least one additional component.

The method may include immersing the device in the LSCT micture.

According to an embodiment of the invention there may be provided a method for designing a cooling scheme, the method comprises:

receiving cooling demands, wherein the cooling demands comprise a temperature range of a device to be cooled; and
defining a lower critical solution temperature (LSCT) mixture that will undergo a liquid-liquid phase separation when flowing through at least one conduit of a cooling system that is thermally coupled to the device, when the device is heated above a predetermined temperature within the temperature range.

The LSCT mixture consists of water and triethyamine

The LSCT mixture may include water, triethyamine and at least one additional component.

The method may include defining at least one parameter of the cooling system to prevent the LCST mixture from boiling within the cooling system.

According to an embodiment of the invention there may be provided a cooling system for cooling a device, wherein the cooling system may include at least one conduit through which a lower critical solution temperature (LCST) mixture flows for cooling the device when At least one conduit is thermally coupled to the device.

One or more conduits of the at least one conduit is configured to contact the device while cooling the device.

One or more conduits of the at least one conduit is configured not to contact the device while cooling the device.

A diameter of one or more conduits of the at least one conduit does not exceed few millimeters.

A diameter of one or more conduits of the at least one conduit does not exceed few microns.

A diameter of one or more conduits of the at least one conduit is of an equal magnitude of a size of bubbles formed in the LCST mixture when the LCST mixture boils.

The cooling system may be configured to prevent the LCST mixture from boiling within One or more conduits of the at least one conduit.

A critical point of the LCST mixture is within a temperature range to which an interior of One or more conduits of the at least one conduit is subjected by the device.

The LCST mixture may be arranged to undergo a liquid-liquid phase separation when a temperature of the device exceeds a predefined temperature.

The LSCT mixture may consist of water and triethyamine

The LSCT mixture may include water, triethyamine and at least one additional component.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIGS. 1A-1B illustrate a coexistence curve of the water-triethylamine system and the operations modes according to an embodiment of the invention;

FIG. 2 illustrates an experimental setup according to an embodiment of the invention;

FIG. 3 illustrates a tests ection according to an embodiment of the invention;

FIG. 4 illustrates a free convection experimental setup according to an embodiment of the invention;

FIG. 5 illustrates a heated vertical plate of a free convection experimental setup according to an embodiment of the invention;

FIG. 6 illustrates experimental results for forced convection Nu number obtained with phase separation of the LCST water-TEA system for various T_{w} and Tin and a comparison with the Nu number obtained without phase separation according to an embodiment of the invention;

FIG. 7 illustrates a comparison of the correlation) with the experimental results for the heat transfer amplifications for convective heat transfer with phase separation (with laminar flow—120<Re<1100) according to an embodiment of the invention;

FIG. 8 illustrates a comparison between the experimental results for free convection of single phase CST mixture (critical composition) with the prediction of Eq. 9 (FC Thermal expansion) according to an embodiment of the invention;

FIG. 9 illustrates a free convection from plate during phase separation according to an embodiment of the invention;

FIG. 10 illustrates a density difference caused by temperature change together with equilibrium density curve a according to an embodiment of the invention;

FIGS. 11A-11B illustrate a free convection from a heated vertical plate during phase separation in comparison with the free convection correlation (Eq. 9) and includes graph (a) that shuws Nu vs. the temperature driving force, and graph (b) that shows Nu vs. Ra according to an embodiment of the invention;

FIG. 12 is a comparison of the flow visualized during phase separation on the vertical plate with the UCST (left, acetone hexadecane [9]) and LCST (right, water-TEA) systems for similar temperature difference between the bulk and the wall (DT=4.35° C.) according to an embodiment of the invention;

FIG. 13 Free convection from a heated/cooled (UCST/LCST systems) vertical plate during phase separation. Comparisons of AF data with the prediction by Eq. (14) according to an embodiment of the invention;

FIG. 14 illustrates a method according to an embodiment of the invention;

FIG. 15 illustrates a method according to an embodiment of the invention; and

FIG. 16 illustrates a cooling system and a device according to an embodiment of the invention.

### DETAILED DESCRIPTION OF THE DRAWINGS

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Any reference in the specification to a method should be applied mutatis mutandis to a system capable of executing the method.

Any reference in the specification to a system should be applied mutatis mutandis to a method that may be executed by the system.

The term “Lower Critical Solution Temperature (LCST)” is a critical temperature below which the components of the mixture are miscible for all compositions. In various example the mixture is illustrated as being a two-component mixture. The number of components that form the mixture may exceed two. The components that form the mixture may differ from water and treithylamine.

The term “few” means less than ten or twenty.

The terms “system”, “solvant system”, “solution”, “solvant solution”, “mixture” and “solvant mixture”) are used in an interchangable manner.

There are provided experimental results of heat transfer rates obtained during phase separation of a two-component system (two-component mixture) with a LCST. Both convective heat transfer rates in small diameter pipe and over a vertical (hot) plate are reported. This experimental campaign is necessary in order to confirm that phase-separation-induced heat transfer enhancement is feasible also for cooling applications.

2. Experimental Setup and Procedure

2.1 Solvent Mixture. A Water and triethylamine (TEA) mixture with a Lower CST of 18.2° C. was used in various tests.

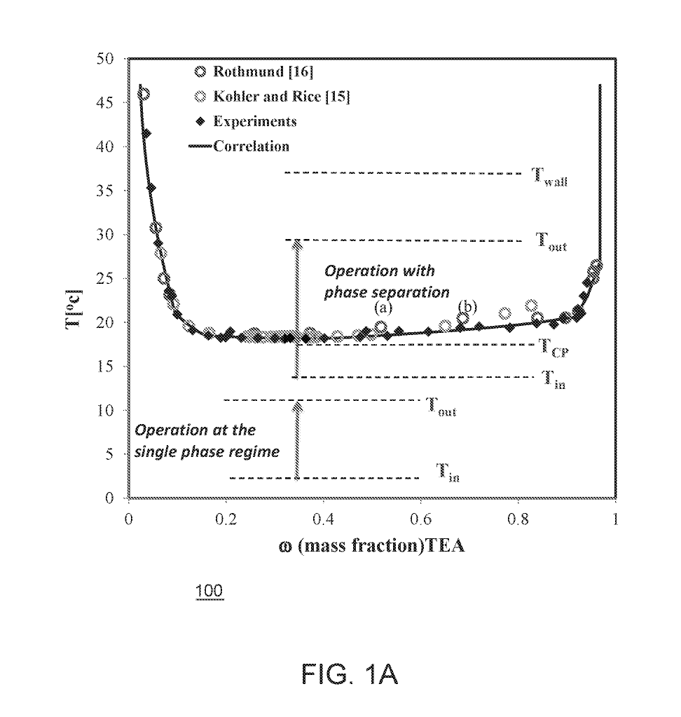

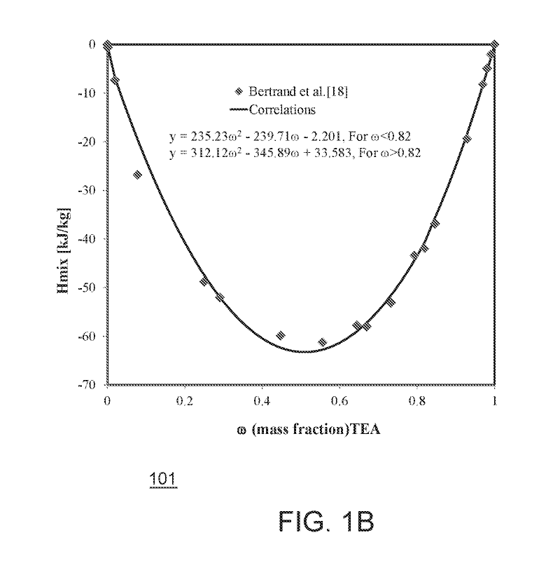

This solvent mixture is nontoxic, nonflammable and the boiling point of triethylamine is around 89.5° C. The co-existence curve (see graph 100 of FIG. 1A) of the water-triethylamine mixture was obtained experimentally using the cloud point procedure [9, 14].

As shown in FIG. 1A, the results of the cloud point experiments are in good agreement with those reported in the literature [15-16]. To accurately represent the co-existence curve data, polynomial curve fitting was used (see graph 100 of FIG. 1A).

The physical properties of the mixture and the two liquid phases were calculated based on the composition and the pure solvent properties. Their variation with temperature was calculated based on correlations from the literature (when available) or by polynomial curve-fitting of data from the literature [17] for the working temperature range and for a constant pressure of 1 atm. The accuracy of the prediction of the mixture density based on the mixture composition and densities of the pure components was tested experimentally. It was found that the non-ideality of the mixture has a negligible effect on the mixture volume and the deviation in the density prediction is less than 1% (in the range of experimental error). The heat capacity of the solvent mixture at various compositions was measured by an in-house calorimeter and compared to available data form the literature [19, 20]. Since the water-triethylamine mixture is a highly non-ideal solution, the heat of mixing should be considered. To this aim, data was taken from Bertrand et al. [18], who measured the heat of mixing in temperature of 15° C. (see graph 101 of FIG. 1B). This temperature was selected as a reference temperature in the energy balance (see Eqs. 3, 4 below).

FIGS. 1A-1B illustrate a coexistence curve of the water-triethylamine mixture and the operations modes: without phase separation (single phase region) and with phase separation; heat of mixing of the water-TEA mixture vs. composition at T=15° C.

The heat transfer studies were conducted with the critical composition of the solvent mixture: 32.1% mass fraction of TEA, which corresponds to phase transition (T_{cp}=LCST=18.2° C.). As the water and TEA have slightly different boiling temperature (and vapor pressure) the mixture was routinely sampled during the experiment and its cloud point and the volume ratio of the separated phases (at room temperature) were monitored to ensure the composition is kept constant.

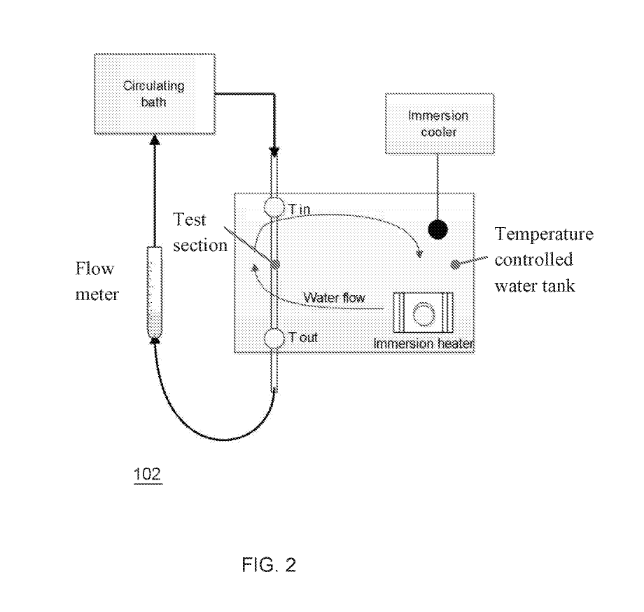

2.2 Heat Transfer in Pipe Flow The experimental setup used is similar to the one described in Ullmann et al. [9]. A schematic diagram of the experimental setup 102 is shown in FIG. 2.

A 30-litre Plexiglas tank of 50 cm length, 30 cm width, and 20 cm height filled with water was used as a temperature controlled environment. The tank was equipped with a circulator, an immersion cooler and a heater which are used for temperature control.

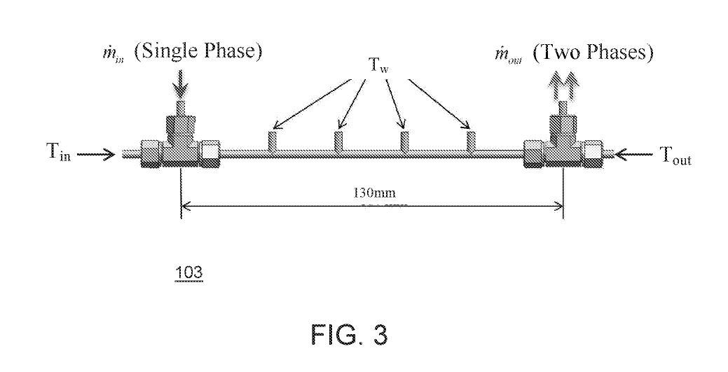

A straight stainless steel (316-L) tube, with an outer diameter of 6 mm and inner diameter of 4 mm, is used as a test section (denoted 103 in FIG. 3). The heat transfer studies are carried in the central section of the tube (131 mm length); the rest of the tube was isolated. The tube is immersed in the water tank, which maintains a uniform temperature of the surface of the test section. The inlet and outlet devices are T junctions. In this arrangement the inlet and outlet streams are perpendicular to the flow in the test section, which enhances the mixing of the fluid at the temperature measurement points. The thermocouples, which are located at the inlet and outlet of the test section, are inserted through the T-shape connectors parallel to the test section. The thermocouple is placed into the Teflon tube and sealed. The purpose of this arrangement is to minimize the effect of the wall temperature on the measurement of the fluid temperature. The whole temperature measurement section was isolated in order to minimize temperature gradient at the temperature measurement location. A data acquisition system NI cDAQ 9174 Of national Instruments, US with NI 9213 16-chanel thermocouple input model of National Instruments, US is used together with LabView software of National Instruments, US to monitor the temperatures.

In addition to the stream inlet and outlet temperatures, the tube inner surface temperature are measured at four locations (spaced evenly). T-type thermocouples are used (FIG. 3). The accuracy of the thermocouple readings is adjusted to ±0.1° C. by using a convergence program of the LabView package. This arrangement enables maintaining conditions of almost constant and uniform wall temperature (the reported values are the average of the 4 thermocouples measurements, where the scattering is less than 0.2° C.).

The CST mixture is cooled in the circulating bath, where the temperature was controlled to the required operating inlet temperature (outside the co-existence curve, i.e. below the cloud point), while the temperature of water in the tank was kept at a constant and uniform temperature. Three modes of operation are possible (FIGS. 1A-1B). In the first mode, the CST mixture enters the test section below the cloud point (T_{cp}) and exits it above the cloud point temperature. In the second mode, the CST mixture enters and exits the test section below the cloud point temperature, but the wall temperature is above the cloud point, causing phase separation at the wall. If the wall temperature is below the cloud point, a third mode becomes possible, where the CST mixture flows as a single phase throughout the test section. In all three modes, the heat transfer rates were tested for different flow rates (measured with 5% accuracy). All the experiments were conducted with laminar flow in the pipe, with Reynolds number varying in the range of Re=120−1100. The Pr number of the solvent mixture is typically in the range of 12 to 17. The reported results correspond to steady state conditions, which are typically achieved after at least five liquid volume replacements in the pipe. In order to calculate the total heat transfer in the pipe test section, the non-ideality of a partial miscible solvent mixture and the associated heat of mixing should be taken into account. An energy balance on a control volume, which represents the pipe test section, reads:

$$\begin{matrix}Q = \dot{m} [ ( {m}_{h} {h}_{h} + {m}_{l} {h}_{l} ) - {h}_{mix} ] ; \dot{m} = {ρ}_{mix} \dot{V} & ( 1 ) \\ {m}_{h} = \frac{{\dot{m}}_{h}}{\dot{m}} = \frac{{ω}_{mix} - {ω}_{l}}{{ω}_{h} - {ω}_{l}} ; {m}_{l} = 1 - {m}_{h} & ( 2 )\end{matrix}$$

The density of the solvent mixture pₘᵢₓ was calculated based on the overall composition and the temperature at the volumetric flow rate (\dot{V}) measurement point. The mass fraction of the heavy and light outlet streams, mₕ and mₗ, were calculated by their composition (in terms of the corresponding mass fraction, w) at the outlet temperature. With T_{ref=}15° C. taken as a reference temperature, the mixture enthalpy at the pipe inlet is given by:

hₘ=Δhₘᵢₓ+Cpₘ(Tᵢₙ−T_{ref}) (3)

Where Δhₘᵢₓ(composition,15° C.)is the heat of mixing for the overall inlet composition (for Tᵢₙ<T_{cp}). It is obtained from data [17] for various compositions at the reference temperature of 15° C. (see FIGS. 1A-1B). The mixture heat capacity, Cpₘ is that of the (non-ideal) mixture (for the mixture composition and the relevant temperature range) Similarly, the enthalpies of the separated heavy and light phases at the test section outlet are given by:

h_{h/l}=Δh_{mix h/l}+Cp_{h/l}(Tₒᵤₜ−T_{ref}) (4)

Where Δh_{mix h/l} and Cp_{h/l} are the heat of mixing and the heat capacity of the heavy/light separated phases at the equilibrium composition corresponding to the outlet measured temperature, Tₒᵤₜ. Using Eq. (1) for obtaining the total heat transferred during phase separation, the heat transfer coefficient, h, is defined by:

$$h = \frac{Q}{{A}_{in} Δ {T}_{lm}} ; Δ {T}_{lm} = \frac{( {T}_{out} - {T}_{w} ) - ( {T}_{in} - {T}_{w} )}{ln \frac{( {T}_{out} - {T}_{w} )}{( {T}_{in} - {T}_{w} )}} \qquad ( 5 )$$

Where T_{w} is the tube inner (constant) surface temperature, DTₗₘ is the log-mean temperature difference and Aᵢₙ is the internal surface area of the test section. The results were compared to the values predicted by the well-established correlation proposed by Hausen [21] for the convective heat transfer in the thermal developing region (the flow in the test section is assumed to be fully developed laminar pipe flow) of pipe with constant wall temperature:

$${Nu}_{D} = 3.66 + \frac{0.0668 Gz}{1 + 0.04 {Gz}^{2 / 3}} \qquad ( 6 )$$

Where Gz=(D/L)Pe (D is the tube inner diameter and L is the length of the test section). The experimental setup and calculation procedure for obtaining the convective heat transfer coefficient were previously tested and validated by conducting control experiments using water flow and single phase flow of the CST mixtures (where the inlet and outlet temperatures are outside the miscibility curve [5,9] and the validity of this correlation to predict the single-phase heat transfer coefficient was confirmed. Therefore, for all practical purposes this correlation can be used as a reference to evaluate the extent of heat transfer enhancement induced by phase separation.

2.3 Free Convection Heat Transfer

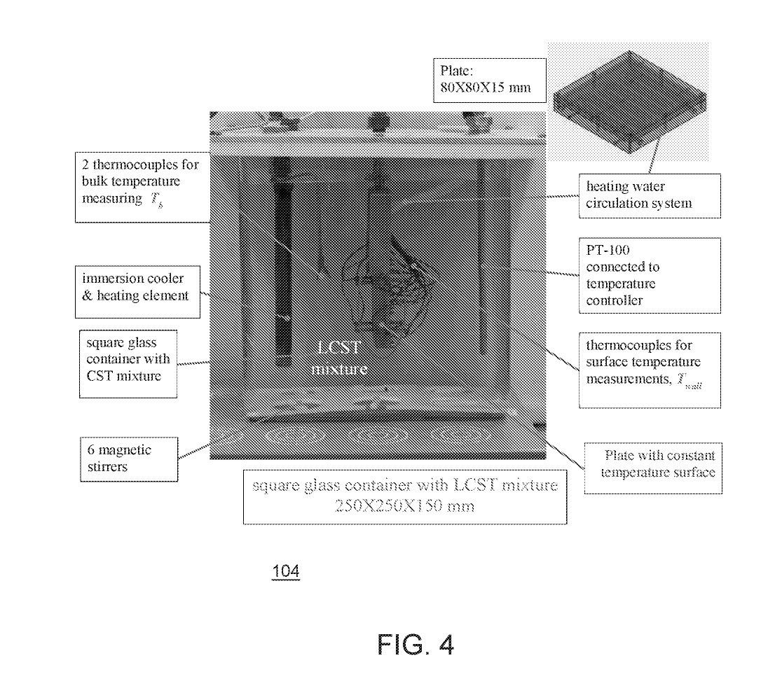

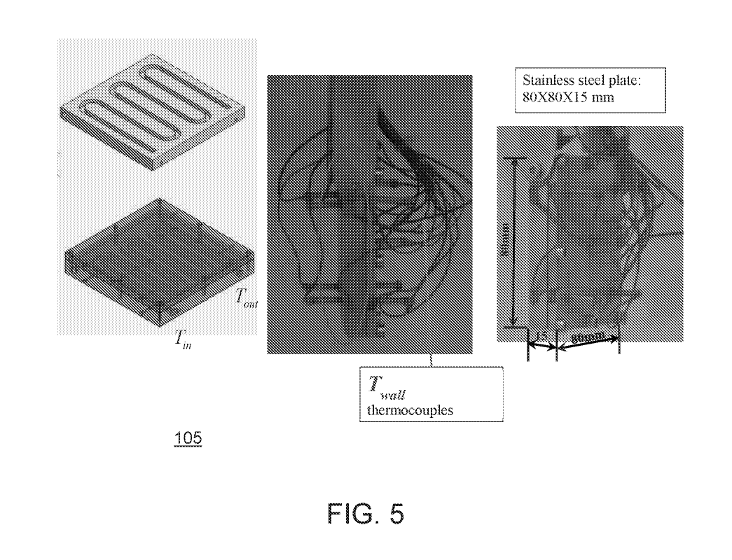

FIG. 4 shows the experimental set-up 104 which is used to conduct experiments on ‘free convection’ from a vertical plate. To this aim, a plate is immersed in a tank filled with the cold (and single phase) CST mixture (with a critical composition). The plate is a square-shaped stainless steel (316-L) plate, 80×80 mm and 15 mm width that is heated by hot water. A temperature controlled bath and a pump are used for circulating heating water through the plate (see T-type thermocupules 105 of FIG. 5). T-type thermocouples are used for measuring the inlet and outlet temperatures of the heating water and the temperature of the plate outer surface (at locations). The thermocouples located on the plate surface were attached by a thermally conductive glue TC-2707 manufactured by 3M Company. Two additional T-type thermocouples and a PT100 sensor are used to measure and control the solvent mixture temperature in the tank.

The CST mixture is contained in a rectangular 6.5-liter glass tank (25 cm length, 14 cm width, and 25 cm height) is used. The tank is covered with a Teflon plate to minimize solvent losses due to evaporation. To enable temperature control of the CST mixture in the bath, heating and cooling elements and a temperature controller are mounted on the Teflon cover plate. Since the operating temperatures of the mixture were below the ambient, Styrofoam 2 cm width plates are attached to the glass walls for thermal isolation. The transparent tank enables visualization of the flow phenomena associated with the ‘free convection’ (to this aim the isolation plates are removed for a short period). The tank is equipped also with 6 magnetic stirrers.

The free convection (with phase separation) experiments are carried according to the following procedure:
a. The solvent mixture is cooled while stirring to a uniform temperature below the cloud point temperature, T_{cp}.
b. The stirrers were switched off, and the solvent mixture in the tank was left to become still (for about 3 minutes).
c. Heating water circulation through the plate was initiated at the maximum possible flow rate for 50 seconds to achieve the required uniform wall temperature (above the T_{cp}) as fast as possible. The heating water flow rate was measured.
d. The bulk temperature of the CST mixture in the tank was constantly monitored and when significant change (more than 1° C.) was observed, the experiment was halted.

The heat transfer rates were tested for different temperature differences between the plate surface and the bulk of the solvent mixture. As a reference, experiments were also conducted for similar temperature differences, when both the mixture bulk temperature and the plate surface temperature were below the T_{cp}, and thus without phase separation.

The experimental heat transfer to the plate is calculated by an energy balance on the heating water:

Q=[ρCp\dot{V}(Tᵢₙ−Tₒᵤₜ)]_{water} (7)

Where \dot{V} is the water volumetric flow rate, and Tᵢₙ and Tₒᵤₜ are the inlet and outlet temperatures of the heating water, respectively. The physical properties of the water (r and Cp) were calculated at the average temperature (Tᵢₙ+Tₒᵤₜ)/2.

Considering that the wires and the frame are placed over the narrow upper side of the plate (which disturbs the flow), and since the hot currents flowing upward from the vertical surfaces actually isolate this side from the ambient, the contribution of the heat transferred from the upper side was neglected Similarly, the heat transfer to the lower surface was ignored, since the heat transfer rate from the horizontal lower side is much lower than from the vertical surfaces. Accordingly, the overall heat transfer coefficient is obtained using following expression:

$$h = \frac{Q}{{A}_{vert} ( {T}_{w} - {T}_{b} )} \qquad ( 8 )$$

Where Aᵥₑᵣₜ is the area of the four vertical surfaces, T_{w} is the surface (average) temperature and Tb is the far field temperature of the CST mixture in the tank. Due to the plate internal design, combined with the high circulating heating water flow rate, the temperature of the plate surface was practically uniform (the maximal temperature difference was below 1.5° C.). It is worth noting that initially, thermocouples were placed on the two wide sides of the plate. To enable a better visualization of the flow over the surface, the thermocouples were removed from one side of the plate. A series of experiments before and after removing the thermocouples provided similar results which suggest that the interference of the thermocouple is minimal and can be considered as insignificant. The experimental heat transfer coefficient was compared with that predicted by the well-established correlation for free-convection heat transfer from a vertical plate with a constant surface temperature proposed by Churchill and Chu [22]:

$${Nu}_{L} = 0.59 {Ra}_{L}^{0.25} for {10}^{4} < {Ra}_{L} < {10}^{9} , {Ra}_{L} = \frac{g Δρ {L}^{3}}{μ α } \qquad ( 9 )$$

3. Experimental Results and Discussion

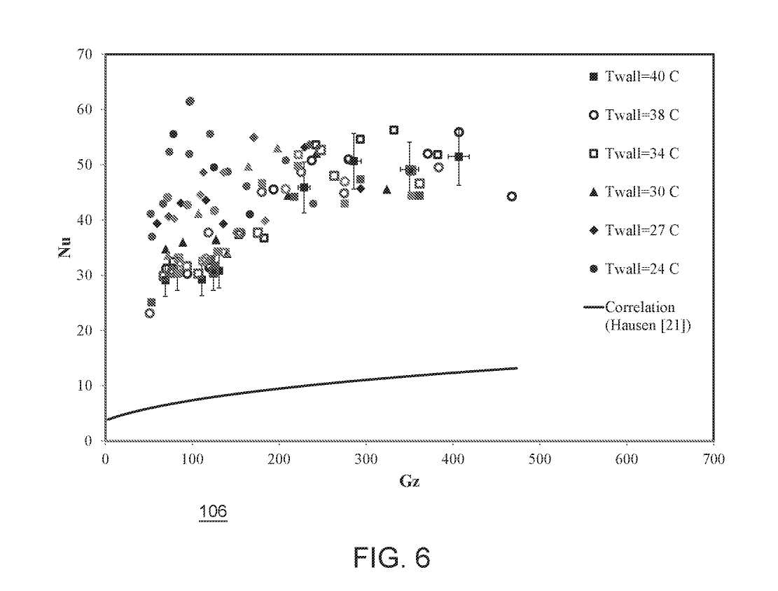

3.1 Convective heat transfer in pipe flow The results for the Nu number vs. the Gz number obtained with phase separation in the test section are depicted in FIG. 6 for different inlet temperature and wall temperatures (above the T_{cp}). In these cases the test section served as a heat sink to the hot water in the tank. The figure clearly shows that the phase separation results in a significant augmentation of the heat transfer rates (compared to single phase Nu number at the same Gz number). To reflect the experimental uncertainty (estimated to be about 10% for the Nu and 5% for the Gz); the error bars for one set of the experimental data are shown in the figure.

The heat transfer enhancement due to the phase separation is represented by the following augmentation factor:

$$AF = \frac{Nu}{{Nu}_{sp}} = \frac{h}{{h}_{sp}} \qquad ( 10 )$$

Where Nuₛₚ is obtained from Eq. (6). Obviously, the overall phenomena are rather complicated. However, it has been postulated [5] that the heat transfer rates are affected by the separating droplets at the vicinity of the wall, their growth rate and lateral velocities. In cases of UCST mixtures these were found to be dependent on the quenching depth and quenching rate. In such mixtures, the quenching depth is defined as (T_{cp}−Tₒᵤₜ) and the quenching rate is represented by (Tᵢₙ−Tₒᵤₜ)U/L, where L/U is the residence time. The quenching depth and rate are normalized by the maximal potential quench (T_{cp}−T_{w}). The term (PeD/L)⁻¹=Gz⁻¹ represents the dimensionless time. In LCST mixtures, the penetration into the (unstable) two-phase region is a result of heating the mixture. Hence, the quenching depth and rate are replaced by the heating depth and rate, respectively.

FIG. 6 includes graph 106 that illustrates experimental results for forced convection Nu number obtained with phase separation of the LCST water-TEA mixture for various T_{w} and Tin=18° C. (Tₒᵤₜ>T_{cp} see FIG. 1)—Comparison with the Nu number obtained without phase separation.

Another influential parameter, which has not been previously considered in analyzing the augmentation factor due to phase separation, is the heat of mixing. In our previous studies with UCST mixtures, e.g., 3-component mixture (water-ethanol-ethyl acetate [5]) and 2-component mixture (acetone-hexadecane, [9]), the heat of mixing was rather small compared to the sensible heat (less than 10% and 25%, respectively). In the LCST (TEA-water) mixture used in this study, the heat of mixing is much more significant (about 30-70% of the sensible heat). The heat of mixing is expected to affect the heat transfer enhancement, as the heat absorbed by the heat of mixing enables maintaining higher temperature gradients at the wall, hence higher heat transfer rates compared to single phase flow. To obtain a unified correlation for the heat transfer enhancement with various UCST and LCST the effect of the Ja number should also be considered in the correlation:

$$Ja = \frac{{Cp}_{mix} ( {T}_{cp} - {T}_{w} )}{Δ {h}_{mix} {\vert}_{{T}_{w}}} \qquad ( 11 )$$

Using these dimensionless variables, the experimental results for AF were found to be represented by the following correlation, which was obtained by a non-linear regression (parameter fitting):

$$AF = 0.964 {Gz}^{0.36} {{Ja}^{- 0.46} ( \frac{{T}_{out} - {T}_{in}}{{T}_{w} - {T}_{cp}} Gz )}^{0.14} {( \frac{{T}_{out} - {T}_{cp}}{{T}_{w} - {T}_{cp}} )}^{0.55} \qquad ( 12 )$$

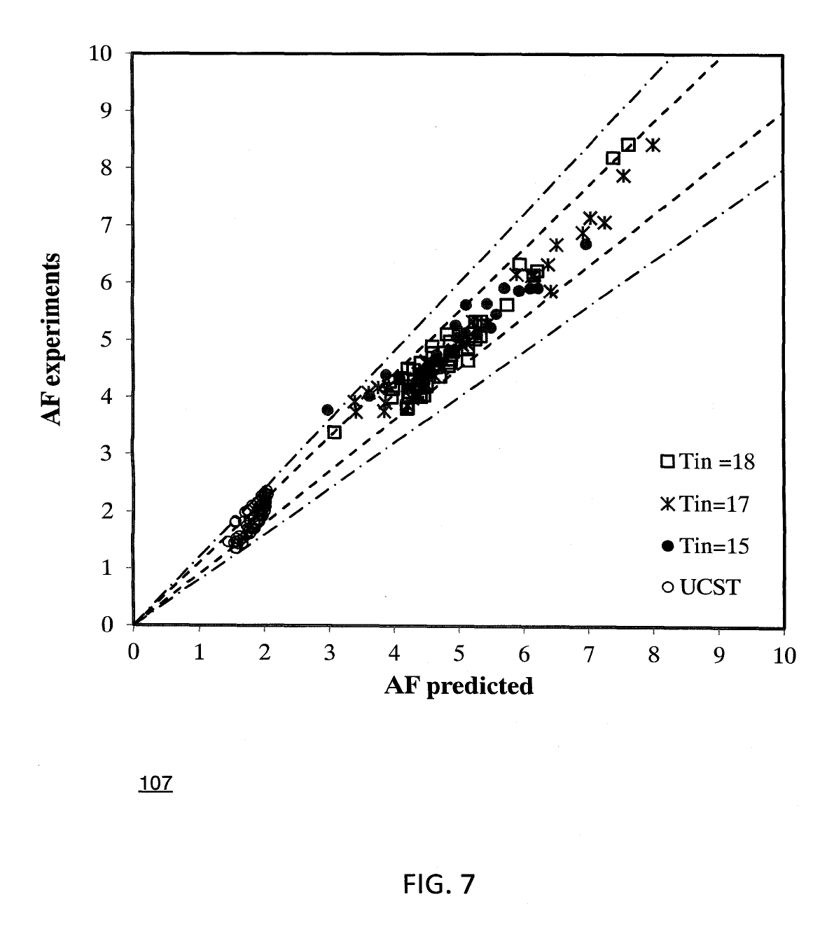

The comparison between the values predicted by Eq. (12) and the experimental AF is shown graph 107 of FIG. 7. The data shown include the AF values obtained for the 2-component acetone-hexadecane UCST mixture [9] and the current results for AF in the LCST mixture. The data obtained with the 3-component (water-ethanol-ethyl acetate [5]) could not be evaluated, as only limited information about the heat of mixing is available for that mixture. Note that the D/L (included in the Gz number), which evolved from normalization of the residence time [5], is different in the two data sets. As can be seen in the figure, the augmentation factors are in the range of 1.5 to (i.e., heat transfer enhancement of 50% to 600%). The agreement between the prediction obtained by the correlation and data is good, with maximum deviations less than about 20%. Considering that the data were obtained with different solvents and in different test-section geometry (i.e., different LID), the agreement between the two sets of data and the correlation is encouraging.

FIG. 7 illustrates a comparison of the correlation (Eq. 11) with the experimental results for the heat transfer amplifications for convective heat transfer with phase separation (with laminar flow—120<Re<1100).

.2 Free Convection Heat Transfer

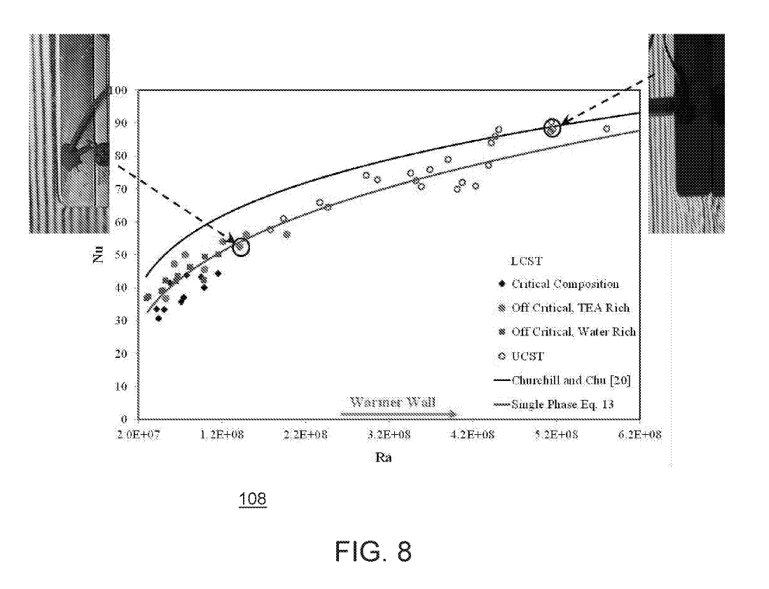

TEA-water mixture was also used to explore the free convection heat transfer phenomena from a vertical plate during phase separation. In order to validate our mixture and experimental procedure described above (see the section on the experimental set-up), free convection experiments with the critical solution mixture, but without phase separation were carried out. FIG. 8 includes graph 108 that shows the experimental Nu numbers vs. the Ra number in comparison with those predicted by Eq.(9). Pictures showing the downward/upward flows of the UCST/LCST (single phase) mixture respectfully in the boundary layer (at the vicinity of the lower plate edge) are attached to the figure. Note that the strips in the background were added to enable visualization of the single-phase flow. Since the wall is warmer than the bulk, the flow in the free convention boundary layer is upward. This is in contrast with the previous experiments with the UCST mixture [9], where the flow near the cooled plate was downward. The agreement with the well-established free convection correlation of Churchill and Chu [22] is acceptable (with a small over prediction), which supports the reliability of the experimental mixture. However, a better representation of the data in the experimental set-up without phase separation is provided by the following correlation:

Nuₛₚ=0.11Ra_{L}^{0.33} (13)

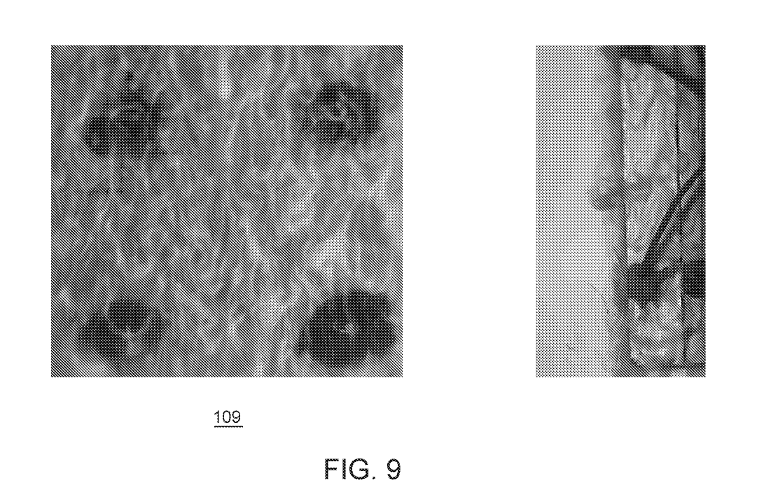

FIG. 9 includes images 109 that show the flow pattern when the temperature of the wall was set above the critical temperature (above T_{cp}), whereby phase separation at the wall was induced. The flow can be easily visualized due to the separating tiny drops which results in a haze like appearance. As shown, in this case an entirely different behavior is observed. Compared to the single phase free convection (FIG. 8), the flow is much more ‘stormy’ with apparent irregular interfacial waves.

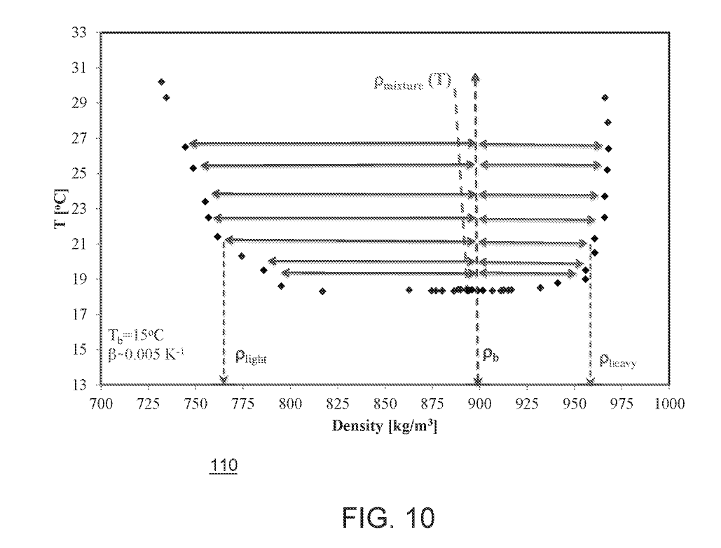

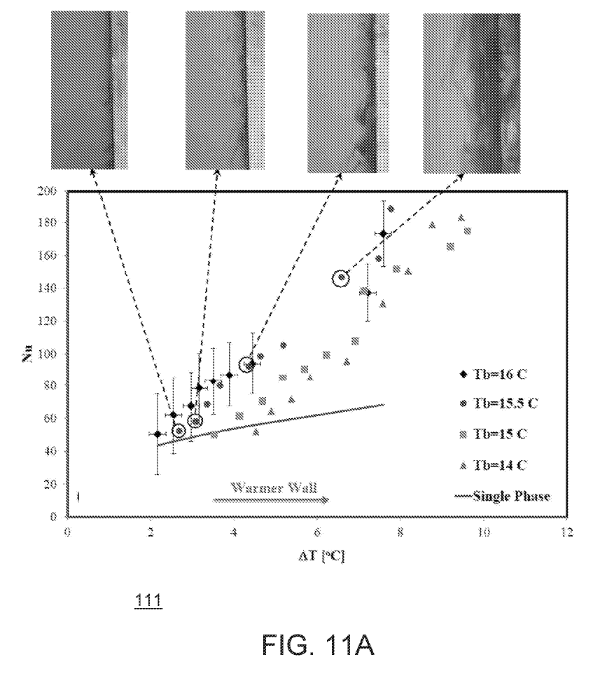

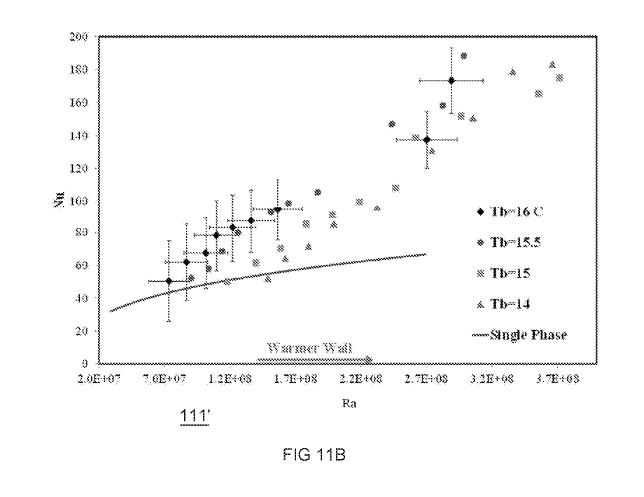

Without phase separation, the driving force for free convection is the density difference due to the thermal expansion (βΔT), whereas in the case of phase separation, the density difference is affected also by the different compositions of the separated phases. For the sake of illustration of the flow driving force, the density difference between the mixture in the bulk and the solutions at the wall temperature, in case composition variations are ignored is shown in graph 110 of FIG. 10. The figure also shows the density differences between the bulk and the separating light and heavy phases. Indeed, in the present solvent mixture composition variations increase the effective density differences. The bulk density in this case is between densities of the light and heavy phases. This complicates the observed flow phenomena, since the flow of the heavy phase, which separates near the heated wall surface, is expected to flow downwards (contrary to the flow direction without phase separation), and only the flow of the light phase is upward. Some impression of the complicated flow field can be obtained from the still photographs shown in FIGS. 9 and the graphs 111 and 11′ of FIGS. 11A and 11B.

Images 109 of FIG. 9 provide a visualization of free convection from plate during phase separation (right—side view, left—front view).

The experimental Nusselt numbers obtained with phase separation (T_{w}>T_{cp}) are presented in graph 111 of FIG. 11A in comparison to the free convection Nu number correlation (Eq. 13). The results clearly indicate that when phase separation takes place, the heat transfer rates are significantly enhanced compared to those obtained for regular free convection (with no phase separation) with the same temperature driving force (T_{w}−T_{b}). Obviously, the minimal temperature difference for inducing phase separation becomes higher as the bulk temperature is decreased. Note that since the experiments were conducted in a container of a finite volume, the experiments were halted when the bulk temperature started to deviate from the initial value (see experimental procedure), possibly before steady state conditions have been reached. Therefore, the full potential of enhancing the heat transfer at a higher temperature difference driving force could not be demonstrated. This limitation is more significant at high (T_{w}−T_{b}), since the change in the bulk temperature and its undesired effects are encountered faster. Graph 111′ of FIG. 11B shows that when phase separation takes place, the Nu number is not solely dependent on the Ra number that is based on the overall composition and temperature driving force. Therefore, for the sake of comparison of the results obtained with and without phase separation and the clarity of the discussion of the phenomena involved, it is preferable to present the Nu number vs. the temperature difference driving force, which is the controllable variable in free convection.

Graph 110 of FIG. 10 illustrates a density difference caused by temperature change together with equilibrium density curve.

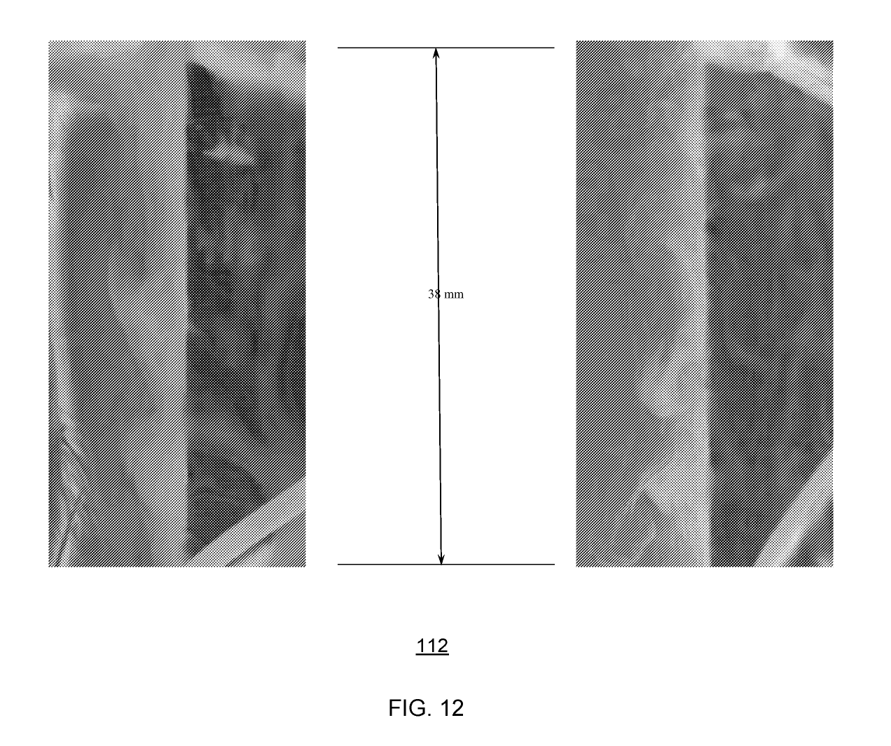

In a previous study conducted by a research group of the inventors [9], the solvent mixture was composed of liquids of almost equal densities, whereby the density difference between the separating phases and the liquid density in the (single phase) bulk was negligible (both the light and heavy phase were slightly heavier than the liquid mixture in the bulk, yet not exceeding 1.3%). In that case the heat transfer enhancement could not be related to the increase of the density difference due to phase separation. The heat transfer enhancement was attributed to the lateral mixing in the film due to the combined effects of the lateral movement of the separating phases and the relative vertical movement of the phases due to density difference. This complicated flow field is manifested in the apparent large interfacial waves. As shown in pictures 112 of FIG. 12, the pictures of the flow taken for the same temperature difference in the UCST and LCST mixtures appear similar, although the corresponding density differences and Ra numbers are very different in the two mixtures, and in the current LCST mixture the movement of the separating phases where in both directions (upward and downward as discussed above). Therefore, the inventors postulated that the mechanisms leading to heat transfer enhancement are similar in the two cases. Indeed, similarly to the results obtained with the ‘equal density’ UCST, FIGS. 11A and 11B show a clear linkage between the increased heat transfer rates and the extent of interfacial irregularities and the flow turbulence. Note however, that in the UCST mixture, where the flow of the two separating phases was downward, film condensation (vapor-to-liquid) modeling approach seemed to be a reasonable starting point for modeling the film flow and the associated heat transfer rates during the liquid-liquid phase separation [9]. Yet, an empirical correlation had to be introduced for representing the enhanced heat transfer at the wavy interface formed between the bulk and the separating film near the wall. In the current mixture, due to the alternate opposite directions of the flow of the two separating phases (as observed in video films of the flow) the film model approach seems to be too simplistic for representing the pertinent transfer phenomena.

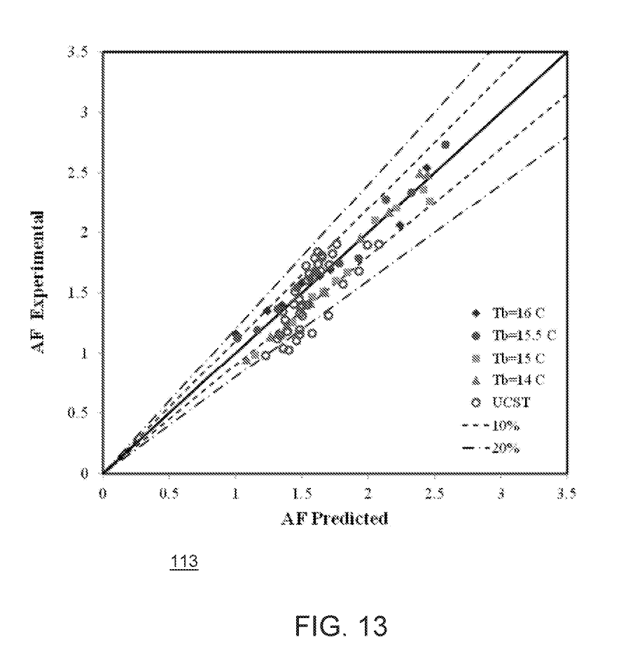

Similarly to the correlation developed for the heat transfer augmentation during liquid-liquid phase separation in pipe flow, here too, an empirical correlation for the free convection heat transfer augmentation was developed in terms of the quenching depth (T_{cp}−T_{w}).

$$AF = \frac{Nu}{{Nu}_{sp}} = \frac{h}{{h}_{sp}} = 0.17 {{Ra}_{L}^{0.12} ( \frac{{T}_{cp} - {T}_{w}}{{T}_{b} - {T}_{cp}} )}^{0.16} \qquad ( 14 )$$

where hₛₚ is that obtained by Eq. (13) (free convection without phase separation) for the same Ra_{L}. As can be seen in graph 113 of FIG. 13, correlation (14) satisfactory represents the current experimental values (within ±20%), indicating that heat transfer augmentation of up to 200% can be reached with the LCST mixture. This correlation also reasonably represents the AF achieved with the previous UCST (equal-density) solvent mixture in the same experimental set-up, which were somewhat lower (up to about 100%). However, it is worth recalling that due to the finite/limited volume of the bulk volume in the container used in the experimental set-up, the full potential of the heat transfer augmentation could not be demonstrated in both cases. It is possible that with a larger volume of the bulk, higher heat transfer augmentation could have been obtained compared to free convection without phase separation.

4. Conclusions

Heat transfer rates obtained during phase separation of a two-component liquid mixture with a Lower Critical Solution Temperature (LCST) composed of water and triethyamine were studied. For cooling applications (i.e., heat sink), the use of a LCST mixture is a pre-requisite for employing liquid-liquid phase separation as a mean for enhancing single phase heat transfer rates. Both convective heat transfer rates in small diameter pipe and over a vertical (hot) plate were tested.

The heat transfer rates obtained with laminar flow in a small diameter pipe indicate that phase separation can improve the convective heat transfer coefficients by 200% to 600% (augmentation factor, AF=3 to 7), and in some cases even higher. The augmentation is attributed to the self-propelled lateral movement of the separating droplets and domains. It is important to note that the augmentation factor actually represent the ratio of the Nu numbers obtained with phase separation to that obtained with single phase of the tested liquid mixture. Therefore, it represents also the augmentation relative to heat transfer rates obtained with any other laminar single phase flow with the same Gz number (for which Eq. 6 is valid). As water is commonly considered to be the preferred choice due to its superior heat transport properties, the augmentation of the heat transfer coefficient obtained with the tested LCST mixture compared to that obtained with water is of particular interest. Although the thermal conductivity of water is higher than that of the solvent mixture (by a factor of almost 2), still the heat transfer coefficient obtained with the phase transition induced heat transfer of the LCST mixture is between 1.5 to 3.5 times that of water. When compared for the same volumetric flow rate, the augmentation is even higher (the Pr number of water is about third of that of the solvent mixture). Note that the viscosity of the mixture is of the same order of that of water (a few percent lower).

Similarly to results previously obtained with the UCST mixtures [5,9], a unified correlation for the heat transfer augmentation factor, AF, could be obtained in terms the quenching rate, quenching depth and the Gz number, which are shown to increase the heat transfer rates. The correlation includes also the Jacob number, to reflect the effect of the heat of mixing and the solvent specific heat, which are much higher in the tested LCST mixture (by about a factor of 2) compared to the previously used UCST mixture. However, as the specific heat is included also in the Gz number, the correlation obtained implies that the main effect of the Ja number is due to the heat of mixing. The possible effect of the Ja number was not considered in our previous studies, since the heat of mixing in the studied UCST mixtures was small compared to the sensible heat. With the new correlation developed, the AF of the UCST and LCST mixture could be reasonably presented, although the physical properties, as well as the tube diameter and length are different in those mixtures.

The tests of natural-convection on a vertical plate with the LCST mixture indicate that phase separation can improve the heat transfer coefficients at the heated plate surface by up to 200% (AF=3) compared to the values obtained without phase separation. The augmentation factor was found to increase with the quenching depth and with the Ra number. The AF values are somewhat larger than those previously obtained with the UCST mixture [9], however of the same order of magnitude, although the density difference between the separating phases and the bulk is almost ten times higher in the LCST mixture. This substantiates our previous conclusion that the effect of the gravitational force on the heat transfer augmentation is of secondary importance and that liquid-liquid phase separation can enhance the heat transfer rates also under micro gravity conditions.

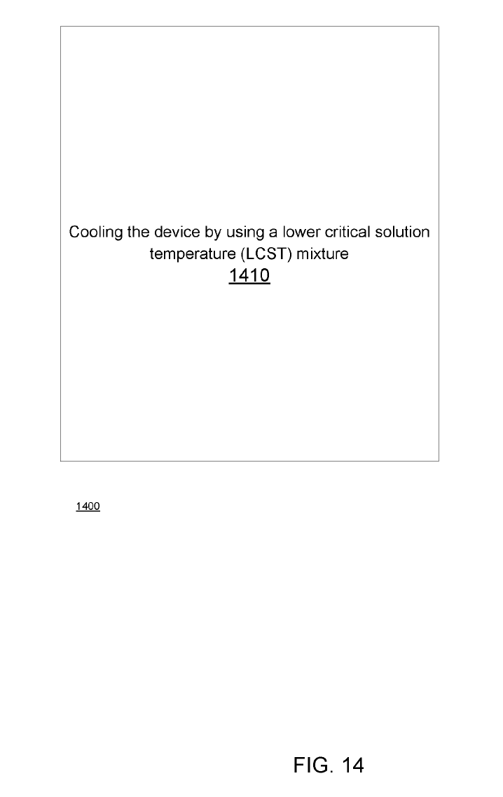

FIG. 14 illustrates a method 1400 according to an embodiment of the invention.

Method 1400 is for cooling a device and includes stage 1410 of cooling the device by using a lower critical solution temperature (LCST) mixture.

Stage 1410 may include cooling the device by providing the LCST mixture to conduit of a cooling mixture, the conduit contacts the device. The conduit may be a small conduit having a millimetric diameter (and/or millimetric cross section) and even smaller diameter (micronic diameter and/or cross section). The cross section of the conduit may be circular or have any other shape. The conduit may be small in the sense that its diameter if of an equal magnitude of a size of bubbles formed in the LCST mixture when the LCST mixture boils. There may be provided multiple conduits. The conduit can be not small—exceed millimetric and even micronic cross section dimensions.

Stage 1410 may include preventing the LCST mixture from boiling within the conduit. For example—this may include determining a pressure level within the conduit that is high enough to prevent the LCST mixture from boiling

The critical point of the LCST mixture is within a temperature range to which an interior of the conduit is subjected by the device. Accordingly—when the device heats (above a predefined temperature)—and heats the LCST mixture within the conduit—the conduit may undergo a liquid-liquid phase separation.

The LSCT mixture may consist of water and triethyamine

The LSCT mixture may include water, triethyamine and at least one additional component.

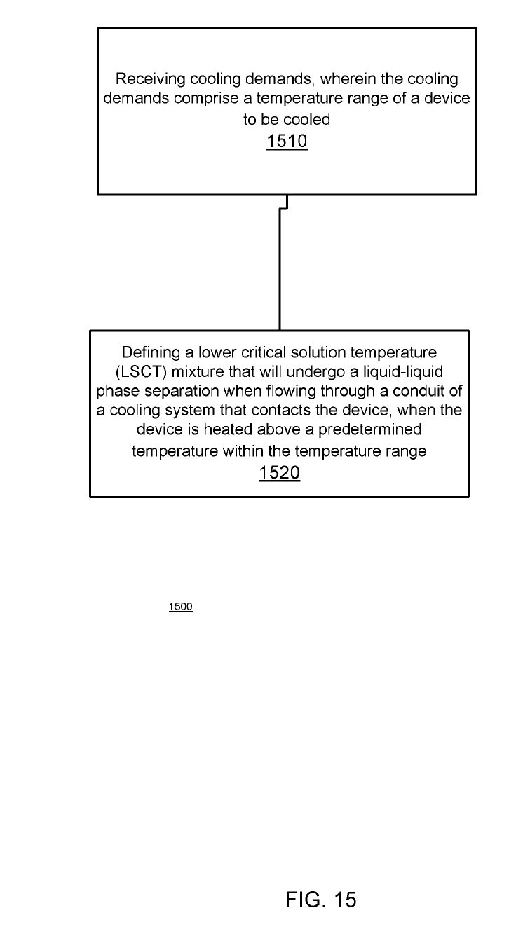

FIG. 15 illustrates a method 1500 according to an embodiment of the invention.

Method 1500 is for designing a cooling scheme, the method may include receiving (1510) cooling demands, wherein the cooling demands comprise a temperature range of a device to be cooled; and defining (1520) a lower critical solution temperature (LSCT) mixture that will undergo a liquid-liquid phase separation when flowing through a conduit of a cooling system, the conduit of the cooling system contacts the device, when the device is heated above a predetermined temperature within the temperature range.

The LSCT mixture may consist of water and triethyamine

The LSCT mixture may include water, triethyamine and at least one additional component.

Stage 1520 may also include defining at least one parameter (such as pressure level) of the cooling system to prevent the LCST mixture from boiling within the cooling system.

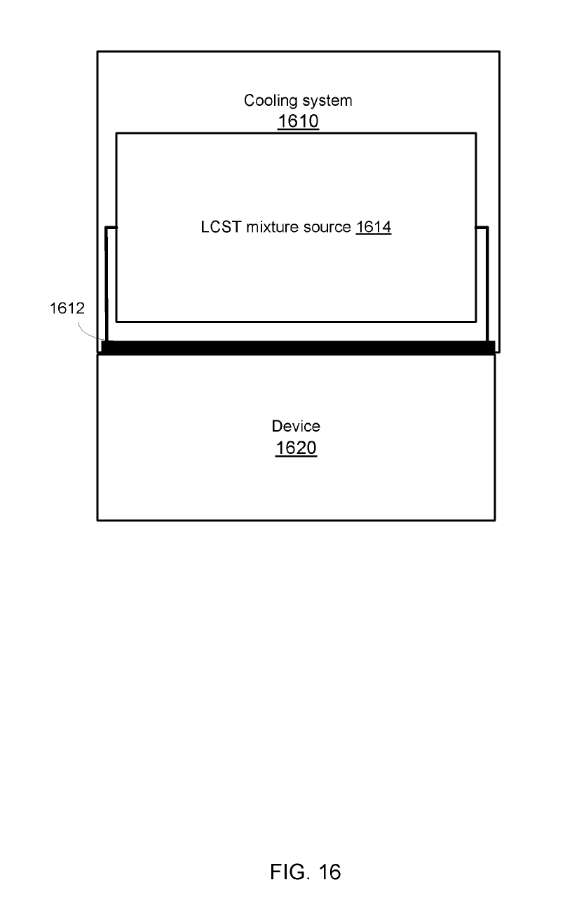

FIG. 16 illustrates a cooling system 1610 and a device 1620 according to an embodiment of the invention.

Cooling system 1610 has a conduit 1612 and a LCST mixture source 1614. Conduit 1612 may be a pipe or may be any type of conduit. LCST mixture source 1614 may be any type of LCST mixture provider that is configured to provide the LCST mixture to conduit 1612. Conduit contacts device 1620 to be cooled or is at least thermally coupled to device 162o. The passage of the LCST mixture through conduit 1612 cools the device 1620.

Cooling system 1610 may have more than a single conduit 1612 that contact the device 1620. More than a single cooling system 1610 may be used to cool device 1620.

### NOMENCLATURE

A surface area [m²]
AF augmentation factor [-]
Cp specific heat [J kg⁻¹° C.⁻¹]
D tube inner diameter [m]
Gz Graetz number [−]
h enthalpy [J kg⁻¹]
hₘᵢₓ heat of mixing [J kg⁻¹]
h heat transfer coefficient [Wm⁻²° C.⁻¹]
Ja Jacobs number [−]
k thermal conductivity [W m⁻¹° C.⁻¹]
L length of the test section [m]
\dot{m} mas flow rate [kg s⁻¹]
m mass fraction of a phase [−]
Nu Nusselt number [−]
Pe Peclet number, UD/α[−]
Pr Prandtl number [−]
Q heat transfer rate [W]
Ra Rayleigh number [−]
Re Reynolds number [−]
T temperature [° C., K]
U average axial velocity [m s⁻¹]
\dot{V} volumetric flow rate [m³ s⁻¹]
   Greek letters
α thermal diffusivity [m²s−1]
β thermal expansion coefficient [K⁻¹]
μ viscosity (Pa s)
ρ density [kg m−3]
ω component mass fraction in the phase

### Subsripts

b bulk
cp cloud point
D diameter as characteristic length
h heavy phase
in in
id ideal
light phase
L plate height as characteristic length
mix mixture
out out
sp single phase
w wall

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim:

1. A method for cooling a device, the method comprises cooling the device by using a lower critical solution temperature (LCST) mixture.

2. The method according to claim 1 comprising cooling the device by providing the LCST mixture to at least one conduit of a cooling system, the at least one conduit is thermally coupled to the device when cooling the device.

3. The method according to claim 1 wherein one or more of the at least one conduit is connected to the device when cooling the device.

4. The method according to claim 1 wherein one or more of the at least one conduit is not connected to the device when cooling the device.

5. The method according to claim 2 wherein a diameter of one or more of the at least one conduit does not exceed few millimeters.

6. The method according to claim 2 wherein a diameter of one or more of the at least one conduit does not exceed few microns.

7. The method according to claim 2 wherein a diameter of one or more of the at least one conduit is of an equal magnitude of a size of bubbles formed in the LCST mixture when the LCST mixture boils.

8. The method according to claim 2 further comprising preventing the LCST mixture from boiling within one or more of the at least one conduit.

9. The method according to claim 2 wherein a critical point of the LCST mixture is within a temperature range to which an interior of one or more of the at least one conduit is subjected by the device.

10. The method according to claim 2 wherein the LCST mixture is arranged to undergo a liquid-liquid phase separation when a temperature of the device exceeds a predefined temperature.

11. The method according to claim 2 wherein the LSCT mixture consists of water and triethyamine.

12. The method according to claim 2 wherein the LSCT mixture comprises water, triethyamine and at least one additional component.

13. The method according to claim 1 comprising immersing the device in the LSCT micture.

14. A method for designing a cooling scheme, the method comprises:
receiving cooling demands, wherein the cooling demands comprise a temperature range of a device to be cooled; and
defining a lower critical solution temperature (LSCT) mixture that will undergo a liquid-liquid phase separation when flowing through at least one conduit of a cooling system that is thermally coupled to the device, when the device is heated above a predetermined temperature within the temperature range.

15. The method according to claim 14 wherein the LSCT mixture consists of water and triethyamine

16. The method according to claim 14 wherein the LSCT mixture comprises water, triethyamine and at least one additional component.

17. The method according to claim 14 comprising defining at least one parameter of the cooling system to prevent the LCST mixture from boiling within the cooling system.

18. A cooling system for cooling a device, wherein the cooling system comprises at least one conduit through which a lower critical solution temperature (LCST) mixture flows for cooling the device when the at least one conduit is thermally coupled to the device.

19. The system according to claim 18 wherein one or more of the at least one conduit is configured to contact the device while cooling the device.

20. The system according to claim 18 wherein one or more of the at least one conduit is configured not to contact the device while cooling the device.

21. The system according to claim 18 wherein a diameter of one or more of the at least one conduit does not exceed few millimeters.

22. The system according to claim 18 wherein a diameter of one or more of the at least one conduit does not exceed few microns.

23. The system according to claim 18 wherein a diameter of one or more of the at least one conduit is of an equal magnitude of a size of bubbles formed in the LCST mixture when the LCST mixture boils.

24. The system according to claim 18 wherein the cooling system is configured to prevent the LCST mixture from boiling within one or more of the at least one conduit.

25. The system according to claim 18 wherein a critical point of the LCST mixture is within a temperature range to which an interior of one or more of the at least one conduit is subjected by the device.

26. The system according to claim 18 wherein the LCST mixture is arranged to undergo a liquid-liquid phase separation when a temperature of the device exceeds a predefined temperature.

27. The system according to claim 18 wherein the LSCT mixture consists of water and triethyamine.

28. The system according to claim 18 wherein the LSCT mixture comprises water, triethyamine and at least one additional component.
